(19) United States
(12) Patent Application Publication
(10) Pub. No.: US 2012/0086448 A1
(43) Pub. Date: Apr. 12, 2012

(54) AMPLIFYING DRIVING UNIT USING GIANT MAGNETO RESISTANCE SENSOR AND DIAGNOSIS DEVICE USING THE SAME

(75) Inventors: Young Muk Kim, Seoul (KR); Jeong Ryul Kim, Seoul (KR); Man Hue Choi, Seoul (KR); Chung Wan Lee, Seoul (KR); Ji Hye Yang, Seoul (KR); Mun Suk Kang, Seoul (KR)

(73) Assignee: LG Innotek Co., Ltd., Seoul (KR)

(21) Appl. No.: 13/257,122

(22) PCT Filed: Mar. 19, 2010
(86) PCT No.: PCT/KR2010/001706

§ 371 Date: Nov. 28, 2011

(30) Foreign Application Priority Data
Mar. 19, 2009 (KR) 10-2009-0023478
Mar. 19, 2009 (KR) 10-2009-0023479

(51) Int. Cl. G01R 33/09; H03F 3/45

(52) U.S. Cl. 324/252; 330/69

(57) ABSTRACT

The present invention relates to an amplifying unit comprising: a pull up down unit pulling up or pulling down a positive GMR signal and a negative GMR signal provide by a GMR sensor; a GMR amplifying unit including a plurality of amplifying units generating a GMR signal by amplifying a difference between the stand-alone type signal and the negative GMR signal according to the GMR sensor; a low pass filtering unit attenuating noise of the GMR signal; a reference converting unit generating a reference voltage having a predetermined range for generating a GMR signal; and a gain converting unit amplifying the GMR signals inputted to the plurality of amplifying units by several ten or hundred times.

### TECHNICAL FIELD

The present invention relates to a diagnosis device having a device being able to enhance the magnitude of magnetic field and an amplifying driving unit being able to detect magnetic field using the device.

### BACKGROUND ART

As an aging society recently comes to begin, the increase of desire for healthful life has enlarged a market of a portable healthy diagnosis system. Especially, the role of a biosenor that can analyze, measure, diagnose, or detect various physiologic substances or chemical substances becomes important.

Since the biosensor uses a selective reaction between molecules, it is needed that the biosensor can reduce interference phenomenon caused by substance that does not join in the reaction and can also detect a target substance with a high sensitivity. Also, it is required that it is possible to manufacture the biosensor on a mass production basis and to monitor results acquired by biosensor in real time wherever a monitoring spot is because the operating speed of biosensor can be raised up until desiring speed.

So far, the research of a biosensor has developed for performing quantitative analysis of specific biologic substances using various methods.

A market regarding the biosensor has already developed such as a portable measurer, e.g., a blood sugar tester, a blood ion ingredient analyzer, or a biometric specimen analyzer that can be used in a medical field or an environment industrial field, and an automatic analyzer for research and development. Also, the market regarding the biosensor is expected to be extended a clinical or medical diagnosis and food cleanliness, agriculture, or a fine chemistry.

Since bio chip technology such as a DNA chip or a protein chip that can be used for investigation of human hereditary information, disease diagnosis, preventive medicine, and mass search of substances proposed for new drug, has been rapidly developed, functions of the biosensor such as diagnosis and mass search besides simple analysis have been recently highlighted.

A biosensor uses a magnetic particle detecting device with a magneto resistance sensor to detect a targeting substance. The magnetic particle detecting device detects a targeting substance using a magneto resistance sensor and magnetic effect caused by a magnetic field provided in a diagnosis cartridge. That is, the magneto resistance sensor of the magnetic particle detecting device detects a magnetization change of a bio-substance coating a magnetic ingredient, i.e., a magnetic signal according to a magnitude change of the magnetic field.

It is important to raise the magnetic field provided by the magnetic particle detecting device such that the magnetic particle detecting device generates an effective magnetic signal using the target bio-substance coating the magnetic ingredient. The distance between the magneto resistance sensor and the target bio-substance coating the magnetic ingredient, the sensitivity of the magneto resistance sensor, an amplifying unit that effectively process a component detected by the change of the magnetic signal play an important role as operation components of a diagnosis device.

It is needed a device that can enhance the magnitude of magnetic field and an amplifying unit that can correctly detect the enhance magnitude of magnetic field.

### DISCLOSURE OF INVENTION

### Technical Problem

The present invention provides an amplifying unit using a giant magneto resistance sensor.

The present invention provides a diagnosis device having a device being able to enhance the magnitude of magnetic field and an amplifying unit being able to detect the magnetic field using the device.

### Solution to Problem

In one general aspect of the present invention, there is provided an amplifying unit comprising: a pull up down unit pulling up or pulling down a positive GMR signal and a negative GMR signal provide by a GMR sensor; a GMR amplifying unit including a plurality of amplifying units generating a GMR signal by amplifying a difference between the stand-alone type signal and the negative GMR signal according to the GMR sensor; a low pass filtering unit attenuating noise of the GMR signal; a reference converting unit generating a reference voltage having a predetermined range for generating a GMR signal; and a gain converting unit amplifying the GMR signals inputted to the plurality of amplifying units by several ten or hundred times.

In some exemplary embodiments, the pull up down unit comprises: a first pull up down unit pulling up or pulling down the positive GMR signal wherein the first pull up down unit includes a first resistor and a second resistor in series and a first capacitor in parallel with the first and the second resistors; and a second pull up down unit pulling up or pulling down the negative GMR signal wherein the second pull up down unit includes a third resistor and a fourth resistor in series and a second capacitor in parallel with the third and the fourth resistors.

In some exemplary embodiments the reference converting unit includes at least a resistor having a predetermined resistance value between several ten ohms and several kilo ohms.

In some exemplary embodiments the instrument amplifying unit, first amplifying unit, and the second amplifying unit includes a low power Operational amplifier.

In some exemplary embodiments, the amplifying unit of claim 3, wherein the instrument amplifying unit, first amplifying unit, and the second amplifying unit further comprises an amplifier to keep the amplified GMR signal in a predetermined range and play a role as a buffering unit attenuating noise of the reference voltage.

In another general aspect of the present invention, A diagnosis device, comprising: a detecting unit detecting a magnetic signal for a bio-substance combined with a magnetic ingredient; an amplifying unit amplifying the magnetic signal while a magnetic force is provided; a signal converting unit obtaining a signal waveform and measured values by digitalizing the magnetic signal; and a signal displaying unit displaying the digitalized magnetic signal as stand-alone Type values.

In some exemplary embodiments, the gain converting unit includes at least a resistor of which resistance depends on the instrument amplifying unit, first amplifying unit, and the second amplifying unit.

In some exemplary embodiments, the diagnosis device of claim 8, wherein the detecting unit comprise: a magnetic resistance sensor sensing a magnetic particle of the bio-substance combined with a magnetic ingredient; and a magnetic force providing unit providing a magnetic force to at least one direction of the magnetic resistance sensor.

In some exemplary embodiments, the diagnosis device of claim 10, wherein the magnetic force providing unit; a first providing unit providing the magnetic force to a horizontal direction of the magnetic resistance sensor; and a second providing unit providing the magnetic force to a vertical direction of the magnetic resistance sensor.

In some exemplary embodiments, the diagnosis device of claim 8, wherein the amplifying unit comprise: a plurality of amplifying units amplifying the magnetic signal; at least a low pass filtering unit removing noise of the magnetic signal; and a signal detecting unit arranged between the plurality of amplifying units and detecting the magnetic signal while the magnetic force is provided.

In some exemplary embodiments, the signal detecting unit removes an accumulated magnetic signal using a capacitor and a bios voltage.

### Advantageous Effects of Invention

The amplifying unit according to the present invention can effectively detect magnetic particles since the amplifying unit uses a giant magneto resistance sensor that has a high MR Ratio and high sensitivity. Also, since the amplifying unit according to the present invention uses a DC voltage, the configuration of amplifying unit by present invention can be simplified more than a normal amplifying unit having a magneto resistance sensor. Also, since the amplifying unit according to the present invention consumes relatively low power, the amplifying unit by present invention has advantage in terms of cost.

A diagnosis device according to the present invention includes a detecting device that has a magnetic providing device which provides magnetic field toward at least one direction of a magneto resistance sensor.

By using the detecting device, a magnetic field can be provided for at least one direction of the magneto resistance sensor to raise magnetization value of bio-substance coating magnetic ingredient and it can raise the sensitivity of diagnosis device.

### BRIEF DESCRIPTION OF DRAWINGS

FIG. 1 depicts an operating principle of a giant magneto resistance (GMR) having a spin valve type according to the present invention.

FIG. 2 is a measuring kit using the GMR sensor having a spin valve type in FIG. 1.

FIG. 3 is a characteristic graph of a GMR sensor according to the present invention.

FIG. 4 is a block diagram of a GMR amplifying unit according to the present invention.

FIG. 5 is a schematic diagram of a GMR amplifying unit according to the present invention.

FIG. 6 is a result graph measured with a GMR amplifying unit according to the present invention.

FIG. 7 is a cross-sectional diagram of a detecting device including a GMR having a spin valve type according to the present invention.

FIG. 8 is a cross-sectional diagram illustrating a magnitude of magnetic field of the detecting device in FIG. 7.

FIG. 9 is a block diagram of an amplifying unit included in the detecting device of FIG. 7.

FIG. 10 is a result graph measured before the amplifying unit of FIG. 9 is used.

FIG. 11 is a result graph measured after the amplifying unit of FIG. 9 is used.

FIG. 12 is a block diagram of a diagnosis device including an amplifying unit and a detecting device according to the present invention.

### BEST MODE FOR CARRYING OUT THE INVENTION

Configuration and operation of the present invention will be described in detail with reference to the accompanying drawings.

### First Embodiment

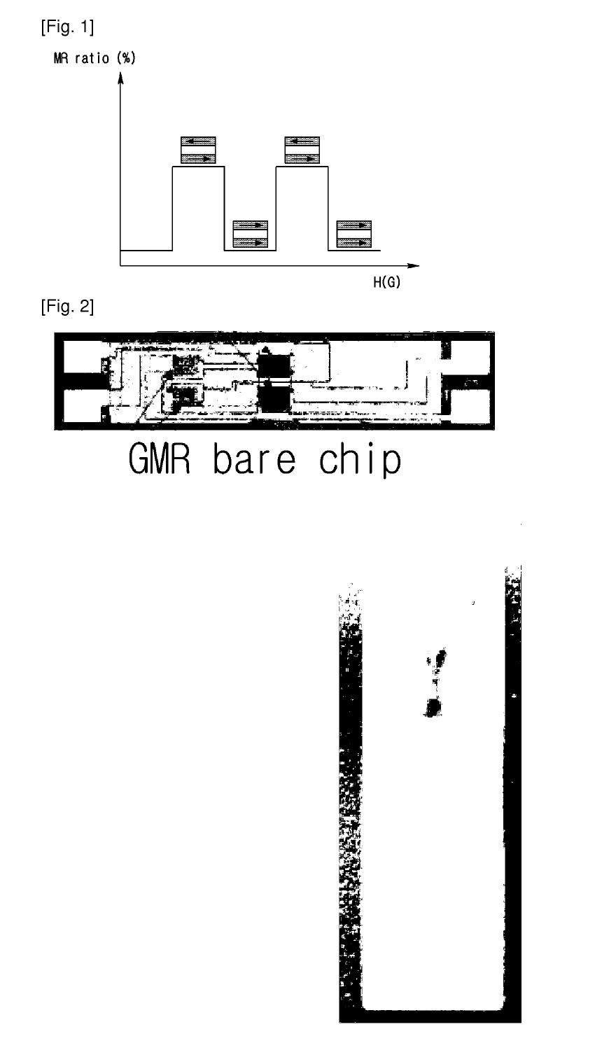

Hereinafter, a first exemplary embodiment according to the present invention will be described referring to FIG. 1 to FIG. 6.

A biosensor is a component that is able to selectively detect a targeting substance to be analyzed by transforming biologic interaction and awareness reaction to an electric signal or optical signal which is provided by an electric or optical transducer connected to biologic objects that can recognize specific substance.

A giant magneto resistance (GMR) may be used to detect a target substance. A plurality of a GMR sensor including a GMR, a switching element and a magnetic element are arranged in a bio sensor. The bio sensor senses magnetic susceptibility depending on ingredients of target substances to analyze an electric ingredient of the target substance.

GMR sensor may have a spin-valve type. FIG. 1 describes operation of a spin-value type GMR device. As shown in FIG. 1, the GMR sensor includes a first ferromagnetic layer, a second ferromagnetic layer, a third nonmagnetic layer arranged between the first ferromagnetic layer and the second ferromagnetic layer. On condition that the first ferromagnetic layer has a fixed polarity, a second ferromagnetic layer has a changeable polarity and a non-magnetic metal layer, when polarities of the first and second ferromagnetic layers are same, i.e., parallel, to each other, electrons spin-aligned in only particular direction can pass through conductive materials. That is, according to polarities of the first and second ferromagnetic layers, there is difference of electro resistance or electrical potential in the sensor. The difference of electro resistance or electrical potential can be converted into a digital signal. When an intervening layer between the first and second ferromagnetic layers is made of a metal, the sensor is called as GMR sensor.

FIG. 2 is a measuring kit using the GMR sensor having a spin valve type in FIG. 1.

As shown, the measuring kit includes at least the GMR sensor with a spin valve type for a bio sensor which configures a electrode pattern. The GMR sensor in the measuring kit may have a standard of 0.3 mm, 0.5 mm, 1.0 mm, 0.25 mm, 1.0 mm, or 1.5 mm. The GMR sensor may have a saturation field of 3˜150 Gauss and have a sensitivity of 0.9˜18 mV/V-0e.

The interface of the GMR sensor receives 5V as a power using a wheatstone bridge and the use a sensing element that can sense 5 k ohms.

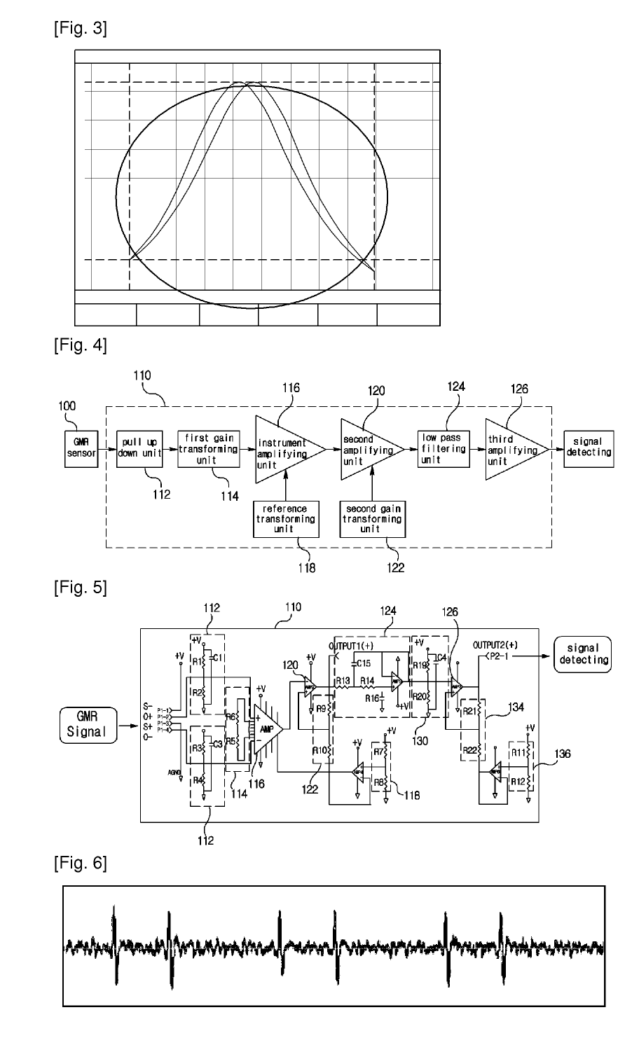

FIG. 3 is a characteristic graph of a GMR sensor according to the present invention.

As shown in FIG. 3, a curve of a magnetic field of the GMR sensor is a symmetric with respect to zero area and a direction of a magnetic field is not detected. A resistance of the GMR sensor decreases by almost same portion in response to a positive or negative magnetic field. A GMR amplification operating device 110 in FIGS. 4 and 5 catches signals detected by the GMR sensor having the graph characteristic of FIG. 3 to extract a correct value.

As shown in FIG. 4, the GMR amplification operating device 110 includes a first pull up down unit 112, a first gain transforming unit 114, an instrument amplifying unit 116, a reference transforming unit 118, a second amplifying unit 120, a second gain transforming unit 122, a low pass filtering unit 124, and a third amplifying unit 126. ‘S−’ denoted in FIG. 5 is a negative power voltage, ‘S+’ denoted in FIG. 5 is a positive power voltage, ‘O−’ denoted in FIG. 5 is a negative GMR signal. ‘O+’ denoted in FIG. 5 is a positive GMR signal.

Herein, the pull up down unit means a pull up circuit or a pull down circuit. The pull up circuit performs an operation of pulling up an input signal, and the pull down circuit performs an operation of pulling down an input signal. The pull up circuit can remove noise of the input signal by pulling up the input signal and the pull down circuit can remove noise of the input signal by pulling down the input signal. Hereinafter, the ‘pull up down’ means pulling up or pulling down.

The pull up down unit 112 includes a first pull up down unit to pull up the positive GMR signal and a second pull up down unit to pull down the negative GMR signal. The pull up down unit 112 attenuates noise of the negative GMR signal and the positive GMR signal and keeps a reference voltage.

The pull up unit includes a first resistor R1, a second resistor R2 which are connected in series, and a first capacitor C1 which are connected to the resistors R1 and R2 in parallel. The pull down unit includes a third resistor R3, a forth resistor R4 which are connected in series, and a second capacitor C2 which are connected to the resistors R3 and R4.

The first pull up down unit pulls up down the positive GMR signal O+ provided from the GMR sensor to send it to a positive input terminal of the instrument amplifying unit 116.

The second pull up down unit pulls up down the negative GMR signal O− provided from the GMR sensor to send it to a negative input terminal of the instrument amplifying unit 116.

The first gain transforming unit 114 amplifies gains of the negative GMR signal O− and the positive GMR signal O+ by several ten or hundred times. The first gain transforming unit 114 includes a resistor R5 and a resistor R6. The resistance of the resistor R5 and the resistor R6 depends on the characteristic of the instrument amplifying unit 116.

The instrument amplifying unit 116 amplifies the difference voltage between the positive GMR signal O+ and the negative GMR signal O− provided by the first and second pull up down units. The positive input terminal of the instrument amplifying unit 116 is connected to the first pull up down unit and the negative input terminal of the instrument amplifying unit 116 is connected to the second pull up down unit. The instrument amplifying unit 116 is connected to the first gain transforming unit 114, the reference transforming unit 118, and the second amplifying unit 120.

The instrument amplifying unit 116 is configured by a low power operational amplifier having 500 khz as a operational range. The instrument amplifying unit 116 may have a gain according to resistances of the resistors R5 and R6 included in the first gain transforming unit 114.

The reference transforming unit 118 provides a reference voltage having a predetermined range which helps the instrument amplifying unit 116 amplify a first amplified GMR signal. The fourth amplifying unit may be connected between the reference transforming unit 118 and the instrument amplifying unit 116 (not shown). The fourth amplifying unit may keep the first amplified GMR signal in a predetermined range and play a role as a buffering unit attenuating noise of the reference voltage.

The reference transforming unit 118 generates the reference voltage corresponding to a predetermined range needed to detect an output signal of the instrument amplifying unit 116 according to the gain change of the instrument amplifying unit 116. Since the reference transforming unit 118 uses analog driving circuit operating with predetermined voltages, the reference transforming unit 118 includes a resistor R7 and a resistor R8 that may have several ten ohms or several kilo ohms referring to noise caused by or level of the predetermined voltages.

The second amplifying unit 120 amplifies the first amplifying GMR signal provided by the instrument amplifying unit 116 to generate a second amplifying GMR signal. The second amplifying unit 120 is connected to the instrument amplifying unit 116. The second amplifying unit 120 is connected to the second gain transforming unit 122 and the low pass filtering unit 124.

The second amplifying unit 120 may be configured by a low power operational amplifier and has 500 khz as a operational range. The second amplifying unit 120 may have a gain according to resistances of resistors R9 and R10 included in the second gain transforming unit 122.

The second gain transforming unit 122 amplifies gains of the first GMR signal inputted into the second amplifying unit 120 by several ten or hundred times. The second gain transforming unit 122 includes the resistor R9 and the resistor R10. The resistance of the resistor R9 and the resistor R10 depends on the characteristic of the second amplifying unit 120.

The low pass filtering unit 124 removes noise of the second amplifying GMR signal provided by the second amplifying unit 120. The low pass filtering unit 124 includes a fifth amplifying unit, and a resistor R13, a resistor R14, a capacitor C15, and a capacitor C16.

The third amplifying unit 126 amplifies the second amplifying GMR signal provided by the low pass filtering unit 124 to generate a third amplifying GMR signal. The third amplifying unit 126 is connected to the low pass filtering unit 124.

The third amplifying unit 126 may be configured by a low power operational amplifier and has 500 khz as a operational range.

The third pull up down unit 130 may are arranged between the third amplifying unit 126 and the low pass filtering unit 124 to pull up down the second amplifying GMR signal. The third pull up down unit 130 includes a resistor R19, a resistor R20 which are connected in series, and a capacitor C4 which are connected to the resistors R19 and R20 in parallel.

The third pull up down unit 130 pulls up down the second amplifying GMR signal provided by the low pass filtering unit 124 to provide it for the third amplifying unit 126.

The third amplifying unit 126 which may be connected to a third gain transforming unit 134 amplifies gains of the third GMR signal inputted into the second amplifying unit 120 by several ten or hundred times. The third gain transforming unit 134 includes a resistor R21 and a resistor R22. The third gain transforming unit 134 may be connected to a reference converting unit 136 to receive a reference voltage having a predetermined range provided by reference converting unit 136.

FIG. 6 is a result graph measured with a GMR amplifying unit according to the present invention. If the GMR amplification operating device 110 as described above is adapted in a GMR sensor, a magnetic particle of the GMR signal can be detected and a clear peak signal in FIG. 6 can be detected.

### Second Embodiment

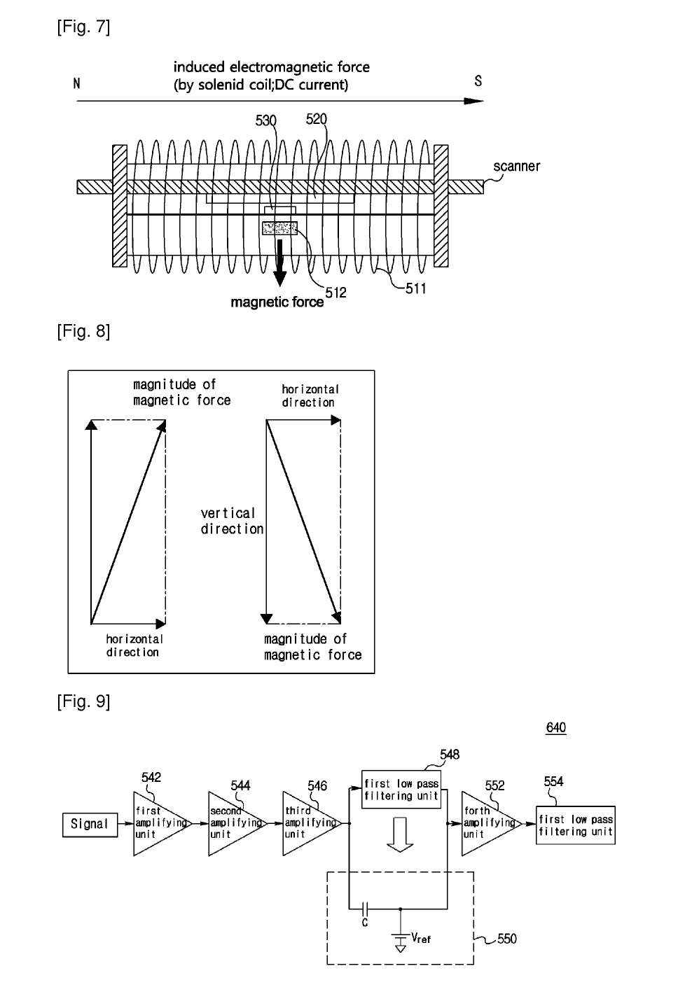

Hereinafter, a first exemplary embodiment according to the present invention will be described referring to FIG. 7 to FIG. 12.

FIG. 7 is a cross-sectional diagram of a detecting device including a GMR having a spin valve type according to the present invention.

Referring to a GMR device having a spin valve type in FIG. 7, a GMR device is a detecting device using a magnetic effect caused by provided a magnetic force at a magnetic resistance sensor and diagnosis kit (cartridge). That is, the magneto resistance sensor of the detecting device detects a magnetization change of bio-substance coating magnetic ingredient, i.e., a magnetic signal according to magnitude change of magnetic field.

The GMR device includes a fixing unit 520 for fixing up a target bio-substance, a magnetic providing unit 511 and 512 for providing a magnetic force to the target bio-substance, and a magnetic resistance sensor 530.

First, the target bio-substance is mounted at the fixing unit 520, and the magnetic providing unit 511 and 512 provides a magnetic force to the target bio-substance. Then, the magnetic resistance sensor 530 senses a magnetic signal for a bio-substance combined with a magnetic ingredient (magnetic particle) and analyzes the magnetic signal.

The magnetic providing unit 511 and 512 provides a magnetic force to at least one direction of the magnetic resistance sensor 530, for example, to a first direction and a second direction of the magnetic resistance sensor 530.

The magnetic providing unit 511 and 512 includes a first providing unit for providing the magnetic force to the first direction, i.e., horizontal direction of the magnetic resistance sensor 530 and a second providing unit for providing the magnetic force to the second direction, i.e., vertical direction of the magnetic resistance sensor 530. Herein, the horizontal direction and the vertical direction of the magnetic resistance sensor 530 do not mean 90 degree angle with the magnetic resistance sensor 530 but may have a predetermined range about an incidence angle of the magnetic force.

The magnetic resistance sensor 530 may be one selected from the group consisting of an Ortrinary Magnetoresistance (OMR) sensor, an Anisotropic Magnetoresistance (AMR) sensor, a Giant Magnetoresistance (GMR) sensor, a Colossal Magnetoresistance (CMR)sensor, a Tunnelling Magnetoresistance (TMR) sensor, a Magnetic Tunneling Junction(MTJ) sensor. Preferably The magnetic resistance sensor 530 includes a GMR sensor.

Since the detecting device includes a magnetic providing unit 511 and 512 that can provides a magnetic force to at least one direction of the magnetic resistance sensor 530, referring to FIG. 8, a magnitude of magnetic force pressed on a particle of a coated bio-substance is a sum of a first magnetic force provided toward the vertical direction of the magnetic resistance sensor 530 and a second magnetic force provided toward the horizontal direction of the magnetic resistance sensor 530. Thus, if the magnetizing force of the bio-substance is raised, the sensitivity of the magnetic resistance sensor 530 can be raised. The amplifying operation unit 640 in FIG. 9 is used to correctly detect a magnetic signal

The amplifying operation unit 640 in FIG. 9 implements an signal process that a sensitivity is enhanced because a magnetization value of bio-substance increase by providing a magnetic force having a predetermined directivity and a predetermined strength to at least one direction of a magnetic resistance sensor. After a magnetic force is provided and the magnitude of the magnetic force is determined, a signal caused by the bio-substance coating a magnetic particle is detected. While the magnetic force is provided, the signal is accumulated and the amplifying operation unit 640 can correctly sense the bio-substance using the accumulated signal. That is, the amplifying operation unit 640 can correctly sense the bio-substance by removing a dummy value corresponding to the accumulated signal.

The amplifying operation unit 640 first amplifies a tiny signal detected by a detecting unit, and then detects a magnetic signal while the magnetic force is provided. The amplifying operation unit 640 includes a first to forth amplifying unit 542, 544, 546, and 552, low pass filters 548, and 554, a signal detecting unit 550.

In FIG. 9, although the amplifying operation unit 640 includes four amplifying unit and two low pass filters, the amplifying operation unit 640 may have more than four amplifying unit and two low pass filters.

The first amplifying unit 542 amplifies a magnetic signal detected the detecting device to generate a first magnetic amplifying signal. The second amplifying unit 544 amplifies the first magnetic amplifying signal to generate a second magnetic amplifying signal. The third amplifying unit 546 amplifies the second magnetic amplifying signal to generate a third magnetic amplifying signal.

The first low pass filter 548 removes noise of the third magnetic amplifying signal provided by the third amplifying unit 546.

The signal detecting unit 550 extracts an original ingredient out of the third magnetic amplifying signal of which noise is removed through the first low pass filter 548. Herein, at least one signal detecting unit is arranged among the plurality of amplifying units. The signal detecting unit 550 uses a capacitor C and a bias voltage Vref to correctly detect concentration of the bio-substance.

The signal detecting unit 550 removes the accumulated signal using the capacitor C and the bias voltage Vref. Hereinafter, there are explanations regarding two cases that the signal detecting unit 550 is not used and used.

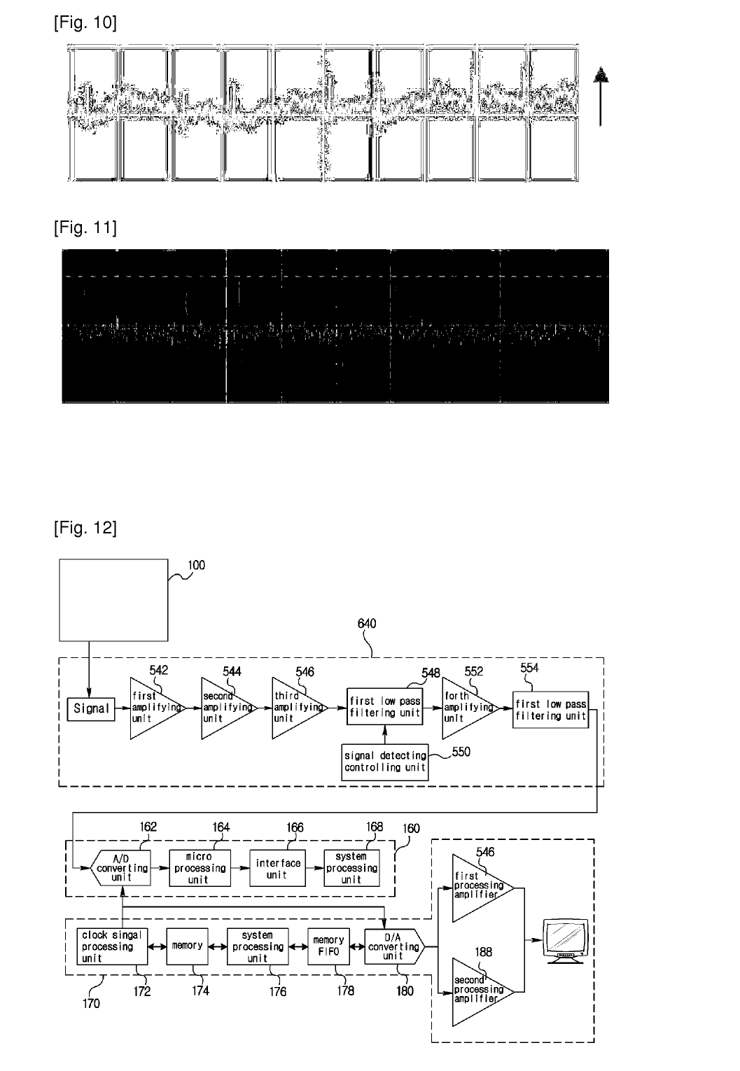

FIG. 10 is a result graph measured before the amplifying unit of FIG. 9 is used. FIG. 11 is a result graph measured after the amplifying unit of FIG. 9 is used.

As times goes, the accumulated signal representing the concentration of the bio-substance increase toward arrow in FIG. 10. Because of the accumulated signal, the graph in FIG. 10 can show a result that cannot be easily recognized by a quantitative analysis. While the magnetic force is provided, because there is not the accumulated signal, an original signal representing the bio-substance can be easily detected.

The role of the capacitor C and the bias voltage Vref in the signal detecting unit 550 is that the amplifying units do not be saturated. In detail, when a magnetic ingredient signal combined with the bio-substance is exposed under an external DC magnetic field, a signal is accumulated because of a conversion signal and a DC ingredient of the magnetic ingredient signal. The amount of accumulated signal becomes larger and if the amount of accumulated signal comes to an operation voltage, the amplifying units is saturated, and then the amplifying units cannot come to detect a signal. A DC ingredient is removed through the capacitor C and the accumulated signal is removed through the capacitor C and a time constant 1/RC after signal the accumulated signal is detected so that the amplifying units is not saturated. Thus, the amplifying units can continually detect a signal because of the capacitor C and the bias voltage Vref.

The fourth amplifying unit 552 amplifies the third magnetic amplifying signal filtered and quantized by the first low pass filter 548 and the third amplifying unit 546 to generate a fourth magnetic amplifying signal.

The second low pass filter 554 removes noise of the forth magnetic amplifying signal. Although there is two low pass filters in FIG. 9, each low pass filter can be corresponded to each amplifying units arranged in an amplifying operation unit of another embodiment.

FIG. 12 is a block diagram of a diagnosis device including an amplifying unit and a detecting device according to the present invention

The detecting device 100 comprises a membrane Kit including a bio-substance, a magnetic field providing unit, a scanner, and a magnetic resistance sensor. The magnetic field providing unit provides a magnetic force for magnetizing the bio-substance of which the direction and magnitude can be adjusted. The magnetic resistance sensor can detect a generated magnetic signal.

The amplifying unit 540 amplifies a tiny signal generated by the detecting unit 500, and detects a magnetic signal while a magnetic field is provided. The amplifying unit 540 amplifies and filters the magnetic signal that is processed by a signal converting unit 160 and a signal displaying unit 170. The amplifying unit 540 includes first to fourth amplifying units 542, 544, 546, and 552, first and second low pass filter 548 and 554, and a signal detecting 550. The first to fourth amplifying units 542, 544, 546, and 552 are for amplifying a signal and the first and second low pass filters 548 and 554 are for removing noise of the signal. The signal detecting 550 can detects a magnetic signal while a magnetic force is provided.

The signal converting unit 160 digitizes an amplified magnetic signal using a computer to obtain a waveform and measured values corresponding to the amplified magnetic signal. The signal converting unit 160 includes an analog-digital converter 162, a microprocessor 164, an interfacing unit 166, and a system processor 168.

The signal displaying unit 170 displays the amplified magnetic signal digitized by the signal converting unit 160 as stand-alone type waveforms and measured values. The signal displaying unit 170 includes a clock signal generating unit 172, a memory 174, a system processing unit 176, a memory FIFO 178, a D/A converting unit, a first processing amplifier and a second processing amplifier. Herein the stand-alone type signal means a waveform and a quantitative value corresponding to a magnitude of a bio-substance combined with a magnetic ingredient and a user can easily recognize the state of the target bio-substance with the stand-alone type signal.

It will be apparent to those skilled in the art that various modifications and variation can be made in the present invention without departing from the spirit or scope of the invention. Thus, it is intended that the present invention cover the modifications and variations of this invention, provided they come within the scope of the appended claims and their equivalents.

1. An amplifying unit comprising:
a pull up down unit pulling up or pulling down a positive GMR signal and a negative GMR signal provide by a GMR sensor;
a GMR amplifying unit including a plurality of amplifying units generating the GMR signal by amplifying a difference between the positive GMR signal and the negative GMR signal according to a characteristic of the GMR sensor;
a low pass filtering unit attenuating noise of the GMR signal;
a reference converting unit generating a reference voltage having a predetermined range for generating a GMR signal; and
a gain converting unit amplifying the GMR signal inputted to the plurality of amplifying units by several ten or hundred times.

2. The amplifying unit of claim 1, wherein the pull up down unit comprises:
a first pull up down unit pulling up or pulling down the positive GMR signal wherein the first pull up down unit includes a first resistor and a second resistor in series and a first capacitor in parallel with the first and the second resistors; and
a second pull up down unit pulling up or pulling down the negative GMR signal wherein the second pull up down unit includes a third resistor and a fourth resistor in series and a second capacitor in parallel with the third and the fourth resistors.

3. The amplifying unit of claim 1, wherein the GMR amplifying unit includes:
an instrument amplifying unit generating a first GMR signal by amplifying a difference voltage between the positive GMR signal and the negative GMR signal;
a first amplifying unit amplifying the first GMR signal to generate a second GMR signal; and
a second amplifying unit amplifying the second GMR signal to generate a third GMR signal.

4. The amplifying unit of claim 3, wherein the gain converting unit includes at least a resistor of which a resistance depends on characteristics of the instrument amplifying unit, first amplifying unit, and the second amplifying unit.

5. The amplifying unit of claim 3, wherein the reference converting unit includes at least a resistor having a predetermined resistance value between several ten ohms and several kilo ohms.

6. The amplifying unit of claim 3, wherein the instrument amplifying unit, first amplifying unit, and the second amplifying unit includes a low power operational amplifier.

7. The amplifying unit of claim 3, wherein the instrument amplifying unit, first amplifying unit, and the second amplifying unit further comprises an amplifier to keep the amplified GMR signal in a predetermined range to play a role as a buffering unit.

8. A diagnosis device, comprising:
a detecting unit detecting a magnetic signal for a target bio-substance combined with a magnetic ingredient;
an amplifying unit amplifying the magnetic signal while a magnetic force is provided;
a signal converting unit obtaining signal waveforms and measured values by digitalizing the magnetic signal; and
a signal displaying unit displaying the digitalized magnetic signal as stand-alone Type values.

9. The diagnosis device of claim 8, wherein the stand-alone Type values includes waveforms and quantitative values corresponding to a magnitude of the target bio-substance combined with a magnetic ingredient.

10. The diagnosis device of claim 8, wherein the detecting unit comprise:
a magnetic resistance sensor sensing a magnetic particle of the target bio-substance combined with the magnetic ingredient; and
a magnetic force providing unit providing the magnetic force to at least one direction of the magnetic resistance sensor.

11. The diagnosis device of claim 10, wherein the magnetic force providing unit;
a first providing unit providing the magnetic force to a horizontal direction of the magnetic resistance sensor; and
a second providing unit providing the magnetic force to a vertical direction of the magnetic resistance sensor.

12. The diagnosis device of claim 8, wherein the amplifying unit comprises:
a plurality of amplifier amplifying the magnetic signal;
at least a low pass filtering unit removing noise of the magnetic signal; and
a signal detecting unit arranged between the plurality of amplifier and detecting the magnetic signal while the magnetic force is provided.

13. The diagnosis device of claim 12, wherein the signal detecting unit removes dummy values accumulated by the magnetic signal and the magnetic force using a capacitor and a bias voltage.
